(19) United States
(12) Patent Application Publication
(10) Pub. No.: US 2006/0024932 A1
(43) Pub. Date: Feb. 2, 2006

(54) Methods of forming semiconductor devices including removing a thickness of a polysilicon gate layer

(76) Inventors: Heung-Sik Park, Seoul (KR); Kyeong-Koo Chi, Seoul (KR); Chang-Jin Kang, Gyeonggi-do (KR)

Correspondence Address: Robert W. Glatz;Myers Bigel Sibley & Sajovec, P.A., P.O. Box 37428, Raleigh, NC, 27627, US

(21) Appl. No.: 11/191,488

(22) Filed: Jul. 28, 2005

(30) Foreign Application Priority Data
Aug. 2, 2004 (KR) 2004-60809

(51) Int. Cl. H01L 21/425

(52) U.S. Cl. 438/530

(57) ABSTRACT

Embodiments of the present invention provide methods of forming a semiconductor device including forming a polysilicon layer on a semiconductor substrate and doping the polysilicon layer with P-type impurities. The semiconductor substrate including the polysilicon layer is annealed and then an upper portion having a first thickness of the annealed polysilicon layer doped with the P-type impurities is removed. The first thickness is selected to remove defects formed in the polysilicon layer during doping and/or annealing thereof.

### PRIORITY STATEMENT

This application claims priority to Korean Patent Application No. 2004-60809, filed on Aug. 2, 2004 in the Korean Intellectual Property Office, the disclosure of which is incorporated herein by reference in its entirety.

### BACKGROUND OF THE INVENTION

The present invention relates to methods of forming a semiconductor device and, more particularly, methods of forming a semiconductor device having a P-channel metal oxide semiconductor (PMOS).

Semiconductor devices having a PMOS region/device are used, for example, for complementary metal oxide semiconductor (CMOS) devices. A CMOS semiconductor device generally includes a P-channel MOS transistor and an N-channel MOS transistor that are constructed on a semiconductor device to perform a complementary operation. With CMOS technology, the efficiency and operating speed of the semiconductor device may be increased relative to a PMOS device and a CMOS transistor device may have characteristics similar to a bipolar transistor. CMOS semiconductor devices are typically used for semiconductor devices requiring high speed and performance. With the recent trend of increasing density for finer semiconductor devices, dual polysilicon gate type CMOS devices have been widely used to increase integration density and to improve a threshold voltage characteristic and an operating speed for the devices. In the dual polysilicon gate CMOS type device, polysilicon defining a gate formed in respective channels is typically doped with impurities having the same conduction type as the channel. Advantageously, the dual polysilicon gate typically makes it possible to enhance a function of a channel surface layer and to perform a symmetrical low-voltage operation.

In various methods of forming a dual polysilicon gate, a polysilicon layer for a PMOS polysilicon gate is doped with P-type impurities and a polysilicon layer for an NMOS polysilicon gate is doped with N-type impurities. Each of the doped polysilicon layers is annealed to activate the impurities.

The P-type impurities may be, for example, boron (B) or boron fluoride (BF₂). As boron is typically readily diffused, doped boron may be diffused during an annealing process to reach a gate oxide layer or to be diffused to an underlying semiconductor substrate through the gate oxide layer. This may lead to generation of leakage current, which may be overcome using boron fluoride (BF₂) because BF₂ generally has a lower diffusivity than boron (B). However, if a polysilicon layer is doped with BF₂ and annealed, small voids typically are formed at an upper portion of the polysilicon layer. Referring to FIG. 1, an illustration is provided showing a semiconductor substrate 1, a gate oxide layer 3, a polysilicon layer 5, a tungsten layer 7, and a silicon nitride layer 9 for a mask, which are stacked in the order named. After being doped with BF₂, the polysilicon layer 5 is annealed. The arrows of FIG. 1 indicate voids. As a resistance of a gate electrode generally increases due to the voids, semiconductor devices including such voids may operate at a low speed or may not operate at all.

### SUMMARY OF THE INVENTION

Embodiments of the present invention provide methods of forming a semiconductor device including forming a polysilicon layer on a semiconductor substrate and doping the polysilicon layer with P-type impurities. The semiconductor substrate including the polysilicon layer is annealed and then an upper portion having a first thickness of the annealed polysilicon layer doped with the P-type impurities is removed. The first thickness is selected to remove defects formed in the polysilicon layer during doping and/or annealing thereof.

In some embodiments of the present invention, the P-type impurities are boron fluoride (BF₂). The polysilicon layer may be a conductive layer and there may be defects in the upper portion thereof. Forming the polysilicon layer may include forming the polysilicon layer to a thickness corresponding to the first thickness plus a desired thickness of a remaining polysilicon layer and removing an upper portion may include removing the upper portion to provide a remaining polysilicon layer having the desired thickness.

In other embodiments of the present invention, removing the upper portion of the polysilicon layer doped with the P-type impurities is followed by patterning the polysilicon layer to form a P-type gate electrode. Patterning the polysilicon layer may be preceded by stacking a metal containing layer on a surface of the semiconductor substrate including the polysilicon layer and patterning the polysilicon layer may include concurrently patterning the metal containing layer and the polysilicon layer. The metal containing layer may include tungsten, aluminum, copper, titanium, tantalum, iridium, cobalt, rhodium, platinum, palladium, and/or molybdenum and/or nitrides or suicides thereof.

In further embodiments of the present invention, removing the upper portion of the polysilicon layer doped with the P-type impurities includes planarizing the polysilicon layer. Planarizing the upper portion may include chemical mechanical polishing (CMP) the polysilicon layer.

In other embodiments of the present invention, forming a polysilicon layer is preceded by forming a gate oxide layer on the semiconductor substrate and removing the upper portion of the polysilicon layer is followed by patterning the polysilicon layer doped with the P-type impurities to form a P-type gate electrode and forming P-type impurity source/drain regions proximate to and on opposite sides of the P-type gate electrode. Forming the polysilicon layer may include forming the polysilicon layer to a thickness corresponding to the first thickness plus a desired thickness of a remaining polysilicon layer and removing an upper portion may include removing the upper portion to provide a remaining polysilicon layer having the desired thickness.

In yet further embodiments of the present invention, the semiconductor substrate includes a NMOS region and a PMOS region. Forming the polysilicon layer includes forming the polysilicon layer in the NMOS and the PMOS regions and doping the polysilicon layer in the NMOS and the PMOS regions with N-type impurities. Doping the polysilicon layer includes doping the polysilicon layer with the P-type impurities in the PMOS region and not in the NMOS region. In some embodiments, the semiconductor substrate includes an NMOS region and a PMOS region and doping the polysilicon layer includes doping the polysilicon layer with the P-type impurities in the PMOS region and not in the NMOS region and annealing the semiconductor substrate is preceded by doping the polysilicon layer in the NMOS region with N-type impurities.

In other embodiments of the present invention, the methods further include patterning the polysilicon layer in the NMOS region to form an N-type gate electrode in the NMOS region and forming N-type impurity source/drain regions in the semiconductor substrate proximate to and on opposite sides of the N-type gate electrode. Patterning the polysilicon layer may be preceded by stacking a metal containing layer on a surface of the semiconductor substrate including the polysilicon layer and patterning the polysilicon layer may include concurrently patterning the metal containing layer and the polysilicon layer. The metal containing layer may be at least one material selected from the group consisting of tungsten, aluminum, copper, titanium, tantalum, iridium, cobalt, rhodium, platinum, palladium, and molybdenum.

In yet further embodiments of the present invention, methods of forming a semiconductor device include forming a gate oxide layer and a polysilicon layer doped with N-type impurities on a semiconductor substrate having an NMOS region and a PMOS region. Using a mask layer covering the polysilicon layer in the NMOS region the polysilicon layer in the PMOS region is doped with P-type impurities. The semiconductor device including the polysilicon layer is annealed. An upper portion having a first thickness of the polysilicon layer doped with the P-type impurities is removed. The first thickness is selected to remove defects formed in the polysilicon layer during doping and/or annealing thereof. The polysilicon layer is patterned to form a P-type gate electrode in the PMOS region and to form an N-type gate electrode in the NMOS region. P-type impurity regions are formed in the semiconductor substrate proximate to and on opposite sides of the P-type gate electrode. N-type impurity regions are formed in the semiconductor substrate proximate to and on opposite sides of the N-type gate electrode. Patterning the polysilicon layer may be preceded by stacking a metal containing layer on a surface of the semiconductor substrate including the polysilicon layer and patterning the polysilicon layer may include concurrently patterning the metal containing layer and the polysilicon layer.

In other embodiments of the present invention, methods of forming a semiconductor device include forming a gate oxide layer on a semiconductor substrate having an NMOS region and a PMOS region. An undoped polysilicon layer is formed on an entire surface of a semiconductor substrate where the gate oxide layer is formed. Using a mask covering the polysilicon layer in the PMOS region, the polysilicon layer in the NMOS region is doped with N-type impurities. The semiconductor substrate including the polysilicon layer is annealed. An upper portion of the polysilicon layer doped with the P-type impurities is removed as much as a first thickness. The polysilicon layer is patterned to form a P-type gate electrode in the PMOS region and to form an N-type gate electrode in the NMOS region. A P-type impurity region is formed in the semiconductor substrate disposed on opposite sides of and adjacent to the P-type gate electrode. An N-type impurity region is formed in the semiconductor substrate disposed on opposite sides of and adjacent to the N-type gate electrode.

In some embodiments of the present invention, when the polysilicon layer is formed, the entire polysilicon layer is doped with N-type impurities. When the polysilicon layer is doped with the P-type impurities, a mask layer may be used to cover a polysilicon layer in the NMOS region.

In other embodiments of the present invention, only a polysilicon layer in the PMOS region is doped with the P-type impurities. Before an annealing process is performed, a polysilicon layer in the NMOS region may be doped with N-type impurities. An upper portion of the polysilicon layer doped with the P-type impurities may be removed as much as a first thickness. The polysilicon layer may be patterned to form an N-type gate electrode in the NMOS region and to form a P-type gate electrode in the PMOS region. Before the polysilicon layer is patterned, a metal containing layer may be stacked on an entire surface of the semiconductor substrate. When the polysilicon layer is patterned, the metal containing layer may also be patterned.

### BRIEF DESCRIPTION OF THE DRAWINGS

FIG. 1 is a photograph illustrating problems that may occur in prior art semiconductor device gates.

FIGS. 2A-2B and FIGS. 4-8 are cross-sectional views illustrating methods of forming a CMOS semiconductor device having a dual gate according to some embodiments of the present invention.

FIGS. 3A-3C are cross-sectional views illustrating methods of forming a CMOS semiconductor device having a dual gate according to other embodiments of the present invention.

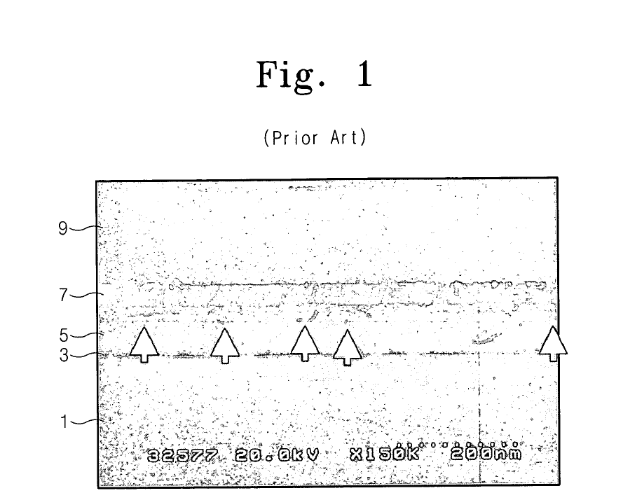

### DETAILED DESCRIPTION OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

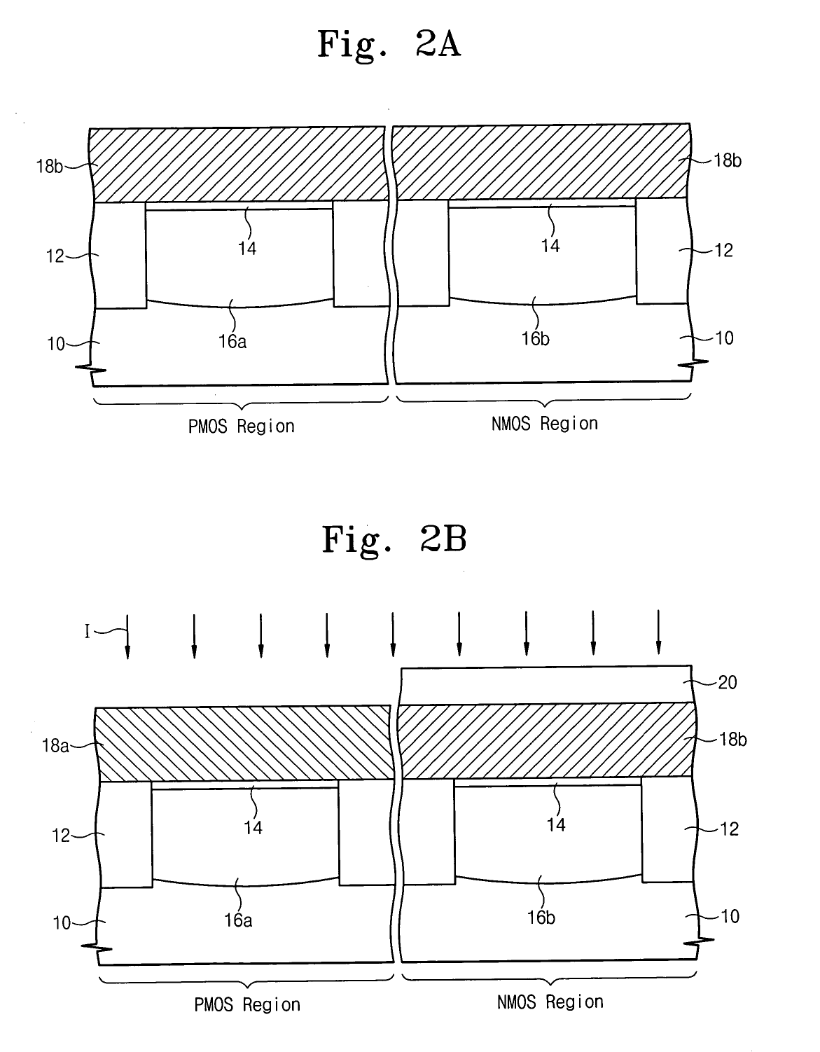

Some embodiments of the present invention will now be described with reference to FIGS. 2A-2B and FIGS. 4-8. FIGS. 2A-2B and FIGS. 4-8 are cross-sectional diagrams illustrating methods of forming a CMOS semiconductor device having a dual gate according to some embodiments of the present invention.

Referring to FIG. 2A, a device isolation layer 12 is formed in a semiconductor substrate 10 having a PMOS region and an NMOS region to define active regions. The formation of the device isolation layer 12 may be done using a shallow trench isolation (STI) technique. Impurities are implanted into the active region to form wells 16a and 16b. The formation of the well 16a in the PMOS region is done by doping the active region with N-type impurities, and the formation of the well 16b in the NMOS region is done by doping the active region with P-type impurities. The N-type impurities may be, for example, at least one material selected from the group consisting of nitrogen, phosphorus, and arsenic. The P-type impurities may be boron and/or boron fluoride (BF₂).

A gate oxide layer 14 is formed on the active region. The formation of the gate oxide layer 14 may be done using a thermal oxidation process and/or a chemical vapor deposition (CVD) process. A polysilicon layer 18b doped with N-type impurities is formed on the gate oxide layer 14. The formation of the polysilicon layer 18b may be done using a CVD process. When a polysilicon layer is deposited, it may be doped with N-type impurities supplied simultaneously. The polysilicon layer 18b may have a thickness of, for example, 400-1000 angstroms (Å). A thickness of the polysilicon layer 18b is equal to the sum of a thickness of a finally remaining polysilicon layer and a thickness of a to-be-removed polysilicon layer. For example, if the thickness of the finally remaining polysilicon layer is 300 angstroms and the thickness of the to-be-removed polysilicon layer is 200 angstroms, an initial thickness of the polysilicon layer 18b is 500 angstroms. A concentration of the N-type impurities is, for example, 1×10¹⁵˜1×10²⁰ ions/cm².

Referring to FIG. 2B, a mask layer 20 is formed to cover the polysilicon layer 18b in the NMOS region. The mask layer 20 may be made of a photoresist pattern and/or silicon nitride. Using the mask layer 20 as an ion implanting mask, P-type impurities are implanted into the polysilicon layer 18b to form the polsilicon layer 18a of FIG. 2B. The P-type impurities in some embodiments are BF₂. The implantation of the P-type impurities may be done at an energy of 1 KeV˜20 KeV and dose of 1×10¹⁵˜1×10²⁰ ions/cm². In order to implant the P-type impurities to a proper depth, their implantation may be done with consideration of a thickness of a polysilicon layer to be removed in a subsequent process (i.e., so that implanted impurities remain in the polysilicon layer after the removal of a thickness thereof). For example, if a polysilicon layer to be finally formed has a thickness of 300 angstroms and the P-type impurities are to be intensively located in a portion thereof to a depth of 200 angstroms and a thickness of a to-be-removed polysilicon is 200 angstroms, the polysilicon layer 18b shown in FIG. 2A should have an initial thickness of 500 angstroms and a target depth of the P-type impurities is 400 angstroms.

Referring to FIG. 4, the polysilicon layer 18a in the PMOS region is annealed under the state of being doped with the P-type impurities. The annealing process may be performed at a temperature of 850° C. for 30 seconds. After the annealing process is performed, defects “D”, i.e., voids may be created at an upper portion of the polysilicon layer 18a doped with the P-type impurities, as previously discussed. The voids “D” are created in the polysilicon layer 18a having a first thickness “T”.

Referring to FIG. 4 and FIG. 5, a portion where the defects “D” are created is removed from the polysilicon layers 18a and 18b. In the case where the first thickness “T” is 200 angstroms, upper portions of the polysilicon layers 18a and 18b may be removed as much as the first thickness. In this case, a planarization process, such as chemical mechanical polishing (CMP) may be performed. To perform the CMP process in some embodiments, silica is used as slurry and a pressure of 2-7 psi is applied while rotating a polishing pad or table at a speed of 40-120 rpm. As illustrated in FIG. 5, the polysilicon layers 18a and 18b have defect-free upper portions.

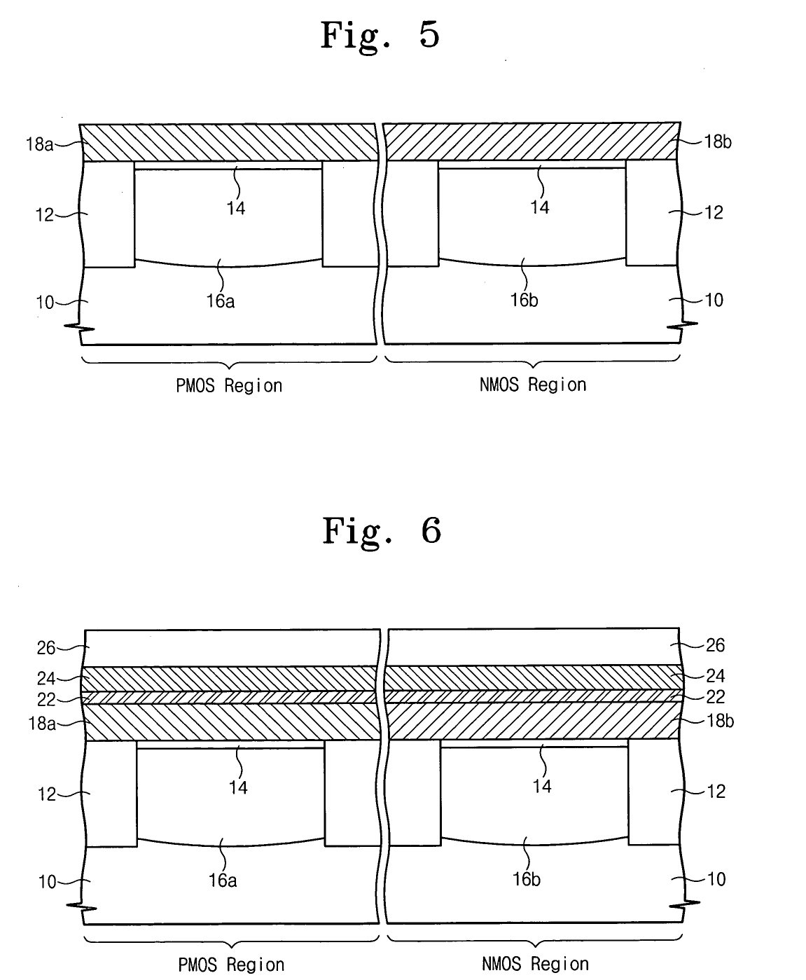

As illustrated in FIG. 6, a first metal containing layer 22, a second metal containing layer 24, and a mask layer 26 are sequentially stacked on an entire surface of a semiconductor substrate where the upper portions of the polysilicon layers 18a and 18b were removed as much as the first thickness “T”. The metal containing layers 22 and 24 may be made of at least one material selected from the group consisting of tungsten, aluminum, copper, titanium, tantalum, iridium, cobalt, rhodium, platinum, palladium, and molybdenum. The first metal containing layer 22 in some embodiments may be, for example, a single layer of tungsten silicide or tungsten nitride or a double layer of tungsten silicide and tungsten nitride. The second metal containing layer 24 may be made of, for example, tungsten. The mask layer 26 may be silicon oxide, silicon nitride or silicon oxynitride.

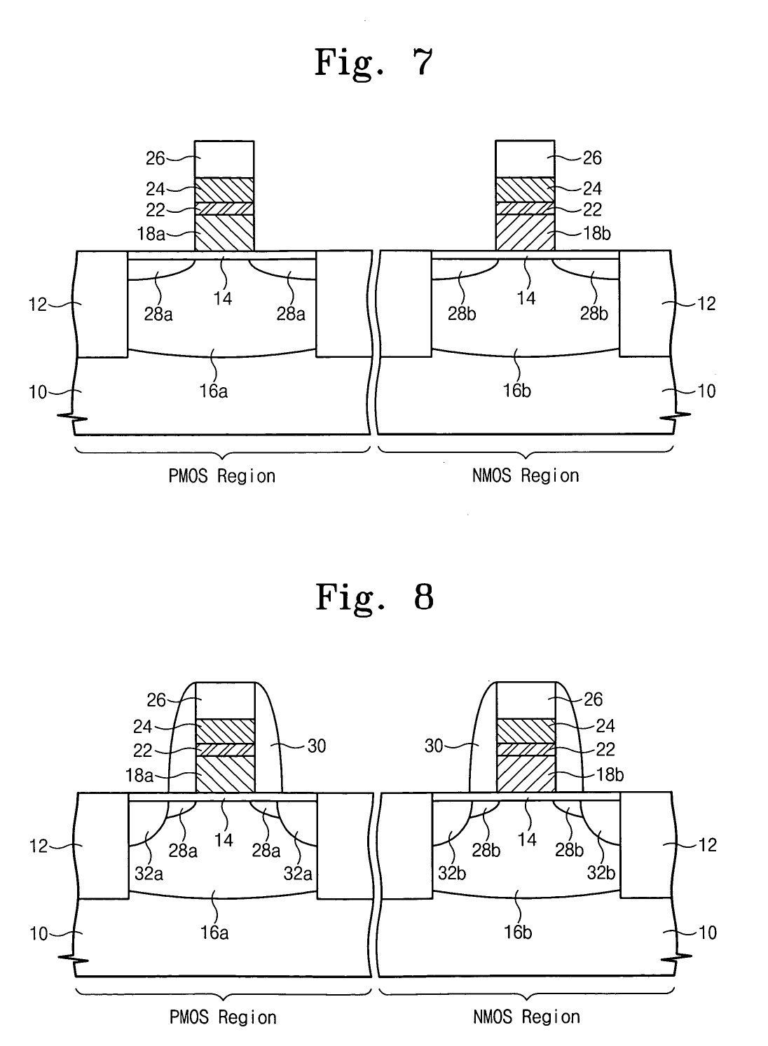

Referring to FIG. 7, the mask layer 26 is patterned using a photoresist pattern (not shown). Using the patterned mask layer 26 as an etch mask, the second metal containing layer 24, the first metal containing layer 22, and the polysilicon layers 18a and 18b are successively patterned to expose the gate oxide layer 14. Thus, a P-type gate electrode is formed in the PMOS region and an N-type gate electrode is formed in the NMOS region. In order to cure an etch damage, a re-oxidation process may be performed. Using the P- and N-type gate electrodes as ion implanting masks, ion implanting processes are performed to form lightly doped impurity areas 28a and 28b in the semiconductor substrate 10 including the wells 16a and 16b. P-type impurities are implanted into the lightly doped impurity area 28a in the PMOS region, and N-type impurities are implanted into the lightly doped impurity area 28b in the NMOS region.

Referring to FIG. 8, a spacer layer is conformally stacked on an entire surface of a semiconductor substrate 10 where the lightly doped impurity areas 28a and 28b are formed. Thereafter, an anisotropic etch is performed to form a spacer 30 covering a sidewall of each gate pattern. Using the spacer 30 and the mask layer 26 as an ion implanting mask, heavily doped impurity areas 32a and 32b are formed in the semiconductor substrate 10. The impurities implanted into the heavily doped areas 32a and 32b in some embodiments are identical to those implanted into the respective lightly doped areas 28a and 28b.

As previously stated, an upper portion of the polysilicon layer 18a with defects “D” is removed. Thus, although metal containing layers 24 and 26 are stacked and patterned to form a gate electrode in a subsequent process, there may be no resulting problems, such as an increase in resistance or a malfunction of a device. As a planarization process for removing the defects “D” may be performed to lower an overall height of the gate pattern, a gap-fill property may become superior and an etch process for forming a gate pattern or a contact hole may be readily performed. Further, a gate polysilicon electrode in a PMOS region may be doped with P-type impurities, for example, BF₂, to limit or even prevent leakage current generated when it is doped with boron.

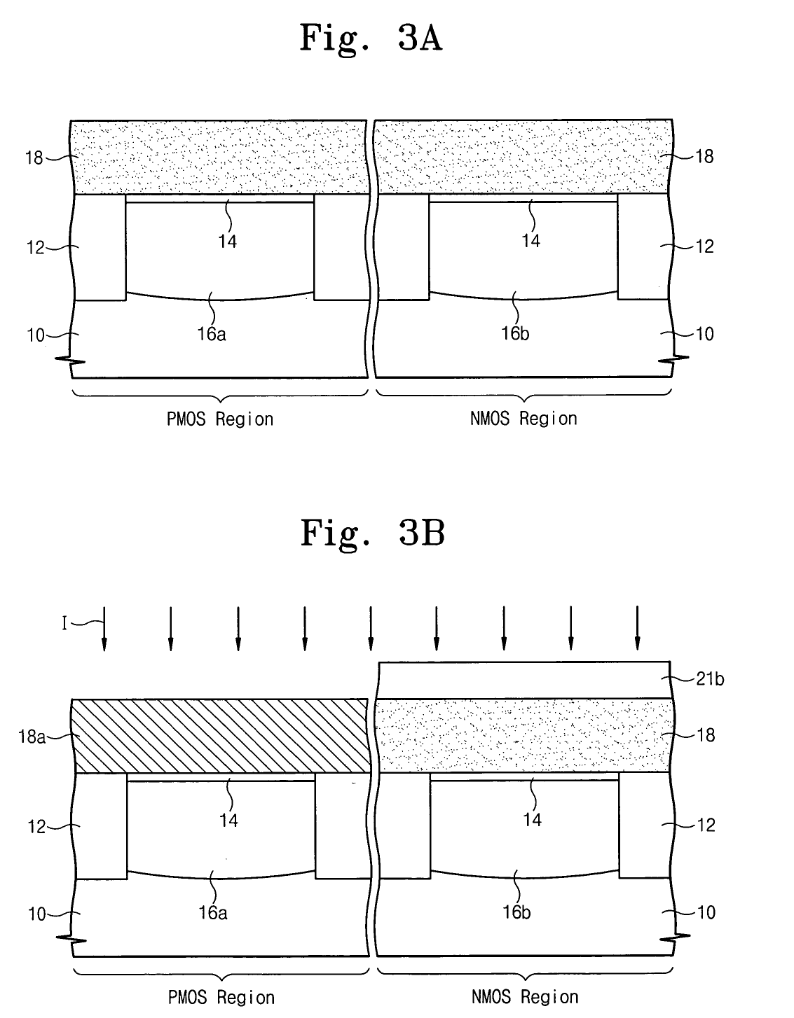

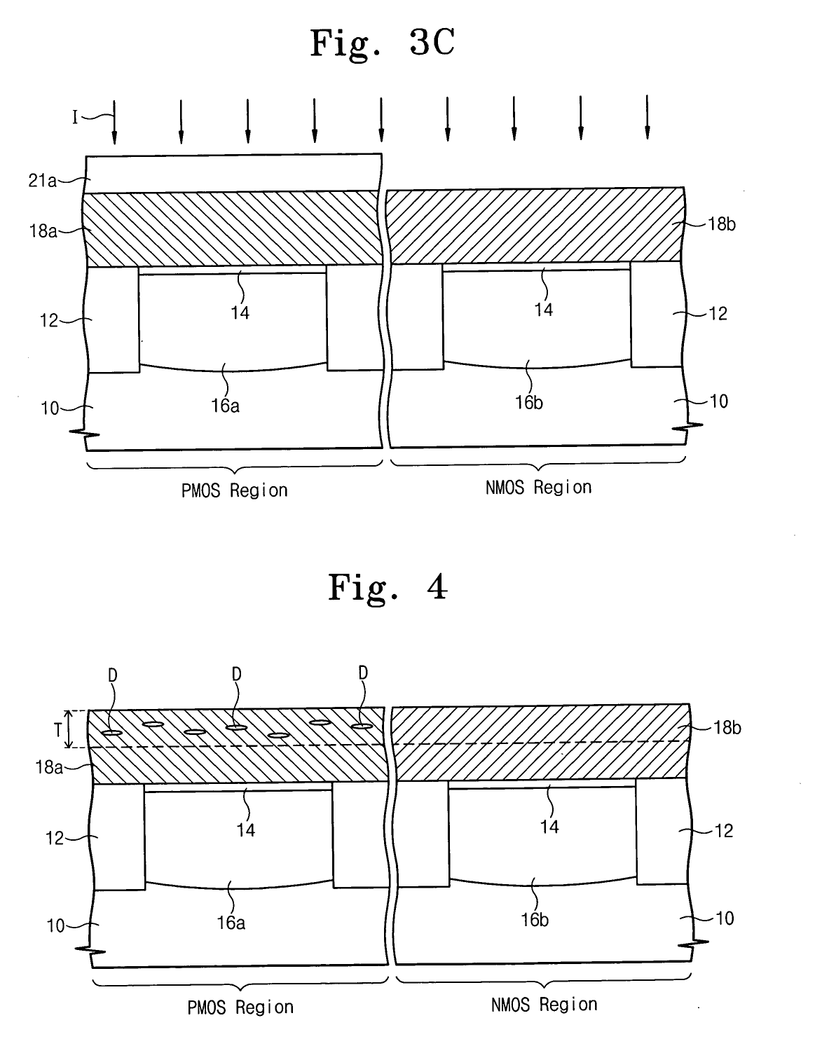

Further embodiments of the present invention will now be described with reference to FIGS. 3A-3C. FIGS. 3A-3C are cross-sectional views illustrating methods of forming a CMOS semiconductor device having a dual gate according to further embodiments of the present invention.

Referring to FIG. 3A, a device isolation layer 12 is formed in a semiconductor substrate 10 having a PMOS region and an NMOS region to define active regions. The formation of the device isolation layer 12 may be done using a shallow trench isolation (STI) technique. Impurities are implanted into the active region to form wells 16a and 16b. The formation of the well 16a in the PMOS region is done by implanting N-type impurities, and the formation of the well 16b in the NMOS region is done by implanting P-type impurities. The N-type impurities may be, for example, at least one material selected from the group consisting of nitrogen, phosphorus, and arsenic. The P-type impurities may be boron (B) and/or boron fluoride (BF₂).

A gate oxide layer 14 is formed on the active region. The formation of the gate oxide layer 14 may be done using a thermal oxidation process and/or a chemical vapor deposition (CVD) process. An undoped polysilicon layer 18 is formed on the gate oxide layer 14. The formation of the polysilicon layer 18 may be done using a CVD process. The polysilicon layer 18 may have a thickness of, for example, 400-1000 angstroms. A thickness of the polysilicon layer 18 is equal to the sum of a thickness of a finally remaining polysilicon layer and a thickness of a to-be-removed polysilicon layer. For example, if the thickness of the finally remaining polysilicon layer is 300 angstroms and the thickness of the to-be-removed polysilicon layer is 200 angstroms, an initial thickness of the polysilicon layer 18 is 500 angstroms.

Referring to FIG. 3B, a mask layer 21b is formed to cover the polysilicon layer 18 in the NMOS region. Using the mask layer 20 as an ion implanting mask, P-type impurities are implanted into the polysilicon layer 18 to form a doped polysilicon layer 18a doped with the P-type impurities in the PMOS region. The P-type impurities in some embodiments are BF₂. The implantation of the P-type impurities may be done at an energy of 1 KeV˜20 KeV and dose of 1×10¹⁰˜1×10²⁰ ions/cm². In order to implant the P-type impurities to a proper depth, their implantation may be done giving consideration to a thickness of a polysilicon layer to be removed in a subsequent process. For example, if a polysilicon layer to be finally formed has a thickness of 300 angstroms and the P-type impurities are to be intensively located at a portion of the finally formed thickness to a depth of 200 angstroms and a thickness of a to-be-removed polysilicon is 200 angstroms, the polysilicon layer 18 shown in FIG. 3A ha an initial thickness of 500 angstroms and a target depth of implantation of the P-type impurities is 400 angstroms. After the ion implanting process is completed, the mask layer 210b covering the NMOS region is removed.

Referring to FIG. 3C, a mask layer 21a is formed to cover the polysilicon layer 18a in the PMOS region. Using the mask layer 21a as an ion implanting mask, N-type impurities are implanted into the polysilicon layer in the NMOS region to form a polysilicon layer 18b doped with the N-type impurities in the NMOS region. The N-type impurities may be at least one material selected from the group consisting of nitrogen, phosphorus, and arsenic. A doping concentration of the N-type impurities may be, for example, 1×10¹⁵˜1×10²⁰ ions/cm². A doping depth of the N-type impurities may be equal to that of the P-type impurities.

After the ion implanting process is completed, the mask layer 21a covering the PMOS region is removed. The mask layers 21a and 21b may be made of photoresist pattern or silicon nitride.

Doping the undoped polysilicon layer 18 with the P-type impurities and doping the undoped polysilicon layer 18 with the N-type impurities are interchangeable with each other. That is, after doping the polysilicon layer 18 in the NMOS region with the N-type impurities using a mask layer covering the PMOS region, the polysilicon layer 18 in the PMOS region may be doped with the P-type impurities using a mask layer covering the NMOS region.

A CMOS semiconductor device having the same dual gate as described with reference to FIGS. 7-8 may further be formed following the operations described with reference to FIGS. 3A-3C in a manner generally described previously with reference to FIGS. 4-8.

Although the present invention has been described with reference to the exemplary embodiments thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

What is claimed is:

1. A method of forming a semiconductor device, comprising:
forming a polysilicon layer on a semiconductor substrate;
doping the polysilicon layer with P-type impurities;
annealing the semiconductor substrate including the polysilicon layer; and then
removing an upper portion having a first thickness of the annealed polysilicon layer doped with the P-type impurities, the first thickness being selected to remove defects formed in the polysilicon layer during doping and/or annealing thereof.

2. The method of claim 1, wherein the P-type impurities comprise boron fluoride (BF₂).

3. The method of claim 1, wherein forming the polysilicon layer comprises forming the polysilicon layer to a thickness corresponding to the first thickness plus a desired thickness of a remaining polysilicon layer and wherein removing an upper portion comprises removing the upper portion to provide a remaining polysilicon layer having the desired thickness.

4. The method of claim 1, wherein removing the upper portion of the polysilicon layer doped with the P-type impurities is followed by patterning the polysilicon layer to form a P-type gate electrode.

5. The method of claim 4, wherein patterning the polysilicon layer is preceded by stacking a metal containing layer on a surface of the semiconductor substrate including the polysilicon layer and wherein patterning the polysilicon layer comprises concurrently patterning the metal containing layer and the polysilicon layer.

6. The method of claim 5, wherein the metal containing layer comprises tungsten, aluminum, copper, titanium, tantalum, iridium, cobalt, rhodium, platinum, palladium, and/or molybdenum and/or nitrides or suicides thereof.

7. The method of claim 1, wherein removing the upper portion of the polysilicon layer doped with the P-type impurities comprises planarizing the polysilicon layer.

8. The method of claim 7, wherein planarizing the upper portion comprises chemical mechanical polishing (CMP) the polysilicon layer.

9. The method of claim 1 wherein forming a polysilicon layer is preceded by forming a gate oxide layer on the semiconductor substrate and wherein removing the upper portion of the polysilicon layer is followed by:
patterning the polysilicon layer doped with the P-type impurities to form a P-type gate electrode; and
forming P-type impurity source/drain regions proximate to and on opposite sides of the P-type gate electrode.

10. The method of claim 9, wherein forming the polysilicon layer comprises forming the polysilicon layer to a thickness corresponding to the first thickness plus a desired thickness of a remaining polysilicon layer and wherein removing an upper portion comprises removing the upper portion to provide a remaining polysilicon layer having the desired thickness.

11. The method of claim 10 wherein removing the upper portion of the polysilicon layer comprises chemical mechanical polishing (CMP) the polysilicon layer.

12. The method of claim 9, wherein the semiconductor substrate includes an NMOS region and a PMOS region and wherein forming the polysilicon layer includes:
forming the polysilicon layer in the NMOS and the PMOS regions; and
doping the polysilicon layer in the NMOS and the PMOS regions with N-type impurities; and
wherein doping the polysilicon layer comprises doping the polysilicon layer with the P-type impurities in the PMOS region and not in the NMOS region.

13. The method of claim 9, wherein the semiconductor substrate includes an NMOS region and a PMOS region and wherein doping the polysilicon layer comprises doping the polysilicon layer with the P-type impurities in the PMOS region and not in the NMOS region and wherein annealing the semiconductor substrate is preceded by doping the polysilicon layer in the NMOS region with N-type impurities.

14. The method of claim 12, further comprising:
patterning the polysilicon layer in the NMOS region to form an N-type gate electrode in the NMOS region; and
forming N-type impurity source/drain regions in the semiconductor substrate proximate to and on opposite sides of the N-type gate electrode.

15. The method of claim 14, wherein patterning the polysilicon layer is preceded by stacking a metal containing layer on a surface of the semiconductor substrate including the polysilicon layer and wherein patterning the polysilicon layer comprises concurrently patterning the metal containing layer and the polysilicon layer.

16. The method of claim 15, wherein the metal containing layer comprises at least one material selected from the group consisting of tungsten, aluminum, copper, titanium, tantalum, iridium, cobalt, rhodium, platinum, palladium, and molybdenum.

17. A method of forming a semiconductor device, comprising:
forming a gate oxide layer and a polysilicon layer doped with N-type impurities on a semiconductor substrate having an NMOS region and a PMOS region;
using a mask layer covering the polysilicon layer in the NMOS region to dope the polysilicon layer in the PMOS region with P-type impurities;
annealing the semiconductor device including the polysilicon layer;
removing an upper portion having a first thickness of the polysilicon layer doped with the P-type impurities, the first thickness being selected to remove defects formed in the polysilicon layer during doping and/or annealing thereof;
patterning the polysilicon layer to form a P-type gate electrode in the PMOS region and to form an N-type gate electrode in the NMOS region;
forming P-type impurity regions in the semiconductor substrate proximate to and on opposite sides of the P-type gate electrode; and
forming N-type impurity regions in the semiconductor substrate proximate to and on opposite sides of the N-type gate electrode.

18. The method of claim 17, wherein patterning the polysilicon layer is preceded by stacking a metal containing layer on a surface of the semiconductor substrate including the polysilicon layer and wherein patterning the polysilicon layer comprises concurrently patterning the metal containing layer and the polysilicon layer.

19. A method of forming a semiconductor device, comprising:
forming a gate oxide layer on a semiconductor substrate having an NMOS region and a PMOS region;
forming an undoped polysilicon layer on an entire surface of a semiconductor substrate where the gate oxide layer is formed;
using a mask covering the polysilicon layer in the PMOS region to dope the polysilicon layer in the NMOS region with N-type impurities;
using a mask covering the polysilicon layer in the NMOS region to dope the polysilicon layer in the PMOS region with P-type impurities;
annealing the semiconductor substrate including the polysilicon layer;
removing an upper portion having a first thickness of the polysilicon layer doped with the P-type impurities, the first thickness being selected to remove defects formed in the polysilcon layer during doping and/or annealing thereof;
patterning the polysilicon layer to form a P-type gate electrode in the PMOS region and to form an N-type gate electrode in the NMOS region;
forming P-type impurity regions in the semiconductor substrate proximate to and on opposites sides of the P-type gate electrode; and
forming N-type impurity regions in the semiconductor substrate proximate to and on opposite sides of the N-type gate electrode.

20. The method of claim 19, wherein patterning the polysilicon layer is preceded by stacking a metal containing layer on a surface of the semiconductor substrate including the polysilicon layer and wherein patterning the polysilicon layer comprises concurrently patterning the metal containing layer and the polysilicon layer.
